(19) United States
(12) Patent Application Publication
(10) Pub. No.: US 2026/0059966 A1
(43) Pub. Date: Feb. 26, 2026

(54) DISPLAY DEVICE

(71) Applicant: SAMSUNG DISPLAY CO., LTD., YONGIN-SI (KR)

(72) Inventors: Jun Geun LEE, Yongin-si (KR); Jun Su LEE, Yongin-si (KR)

(21) Appl. No.: 19/073,735

(22) Filed: Mar. 7, 2025

(30) Foreign Application Priority Data
Aug. 21, 2024 (KR) 10-2024-0111789

(51) Int. Cl. H10K 59/80; H10K 102/00

(52) U.S. Cl. CPC H10K 59/80; H10K 2102/311

(57) ABSTRACT

A display device including: a display panel; and a panel support layer disposed on the display panel, wherein the panel support layer includes: a folding portion, at least one non-folding portion disposed on at least one side of the folding portion, a plurality of bars and a plurality of slits alternately arranged at the folding portion, and at least one cut line disposed between the slits and the non-folding portion.

This application claims priority under 35 U.S. C. § 119 to Korean Patent Application No. 10-2024-0111789 filed on Aug. 21, 2024, in the Korean Intellectual Property Office, the disclosure of which is incorporated by reference herein in its entirety.

### 1. TECHNICAL FIELD

The present disclosure relates to a display device.

### 2. DESCRIPTION OF THE RELATED ART

With the continuous advancement of the information-oriented society, the demand for display devices is steadily increasing. Display devices may include liquid-crystal display devices, field emission display devices, light-emitting display devices, and others. Light-emitting display devices, in particular, can be categorized into organic light-emitting display devices, which use organic light-emitting diodes as light-emitting elements, and inorganic light-emitting display devices, which use inorganic light-emitting diodes.

Recently, to enhance the portability of display devices and offer wider display screens, bendable display devices with flexible displays and foldable display devices with foldable display areas have been introduced to the market.

### SUMMARY

Embodiments of the present disclosure provide a display device including a panel support layer with improved durability.

According to an embodiment of the present disclosure, there is provided a display device including: a display panel; and a panel support layer disposed on the display panel, wherein the panel support layer includes: a folding portion, at least one non-folding portion disposed on at least one side of the folding portion, a plurality of bars and a plurality of slits alternately arranged at the folding portion, and at least one cut line disposed between the slits and the non-folding portion.

A width of the cut line is smaller than a width of one of the plurality of slits.

The at least one cut line includes a first cut line and a second cut line, wherein the first cut line is disposed between the plurality of slits and the non-folding portion, and wherein the second cut line is extended from the first cut line toward the plurality of slits.

The first cut line is extended in a same direction as an extension direction of the plurality of slits, and wherein the second cut line is extended in a different direction from the extension direction of the plurality of slits.

The first cut line further includes a cut hole formed at least one end of the first cut line.

The plurality of slits includes first slits arranged in a first column, second slits arranged in a second column, and third slits arranged in a third column, and wherein the second slits are offset in a direction relative to the first slits and the third slits.

The cut line is parallel to the second slits and is offset in the direction relative to the first slits and the third slits.

The at least one cut line includes a first cut line extended in the direction relative to the first slits and the third slits and a second cut line extended from the first cut line toward the plurality of slits, and wherein a distance between the second cut line and the first slits in the direction relative to the first slits and the third slits is smaller than a distance between the first slits.

The at least one cut line includes a first cut line extended in the direction relative to the first slits and the third slits and a second cut line extended from the first cut line toward the plurality of slits, and wherein a distance between the second cut line and the first slits in the direction relative to the first slits and the third slits is equal to a distance between the first slits.

The at least one cut line includes a plurality of cut lines, wherein the cut lines are spaced apart from each other in the direction relative to the first slits and the third slits, and wherein the bars include spaced bars that are arranged between the cut lines.

A spacing between the cutting lines is equal to a spacing between the second slits.

The slits are extended in a direction different from the direction relative to the first slits and the third slits when the display panel is folded, and wherein lengths of the first to third slits are equal to one another.

The slits contract in the direction relative to the first slits and the third slits when the display panel is folded.

The at least one cut line includes a first cut line extended in the direction relative to the first slits and the third slits and a second cut line extended from the first cut line toward the plurality of slits, and wherein the second cut line is connected with the second slits.

The second cut line is located between the first slits in the direction relative to the first slits and the third slits.

The length of the first slits in the direction is smaller than the length of the third slits in the direction relative to the first slits and the third slits.

The plurality of bars includes first horizontal bars disposed between the first slits, and wherein the first horizontal bars include a first sub-horizontal bar and a second sub-horizontal bar spaced apart from each other with the second cut line therebetween.

According to an embodiment of the present disclosure, there is provided a display device including: a display panel; and a panel support layer disposed on the display panel, wherein the panel support layer includes: a folding portion, a first non-folding portion disposed on a first side of the folding portion, a second non-folding portion disposed on a second side of the folding portion, and a lattice pattern disposed in the folding portion, and wherein the lattice pattern includes: a plurality of bars and a plurality of slits alternately arranged, a first cut line disposed between the plurality of slits and the first non-folding portion, and a second cut line disposed between the plurality of slits and the second non-folding portion.

A width of one of the cut lines is smaller than a width of one of the plurality of slits.

The plurality of slits includes first slits arranged in a first column, second slits arranged in a second column, and third slits arranged in a third column, and wherein the second slits are shifted in a direction relative to the first slits and the third slits.

The cut line is disposed in parallel to the second slits and is shifted in the direction relative to the first slits and the third slits.

Each of the first cut line and the second cut line comprises a vertical cut line and a horizontal cut line, wherein the vertical cut line of the first cut line is disposed between the slits and the first non-folding portion, wherein the vertical cut line of the second cut line is disposed between the slits and the second non-folding portion, wherein the horizontal cut line of the first cut line is extended from the vertical cut line of the first cut line toward the slits, and wherein the horizontal cut line of the second cut line is extended from the vertical cut line of the second cut line toward the slits.

According to an embodiment of the present disclosure, there is provided an electronic device including: a display device that includes: a display panel; and a panel support layer disposed on the display panel, wherein the panel support layer includes: a folding portion, at least one non-folding portion disposed on at least one side of the folding portion, a plurality of solid sections and a plurality of apertures alternately arranged at the folding portion, and a cut line disposed between the apertures and the non-folding portion.

### BRIEF DESCRIPTION OF THE DRAWINGS

The above and other features of the present disclosure will become more apparent by describing in detail embodiments thereof with reference to the attached drawings, in which:

FIG. 1 is a perspective view showing a display device according to an embodiment of the present disclosure when it is unfolded;

FIG. 2 is a perspective view showing the display device according to the embodiment of the present disclosure when it is folded;

FIG. 3 is a perspective view showing a display device according to another embodiment of the present disclosure when it is unfolded;

FIG. 4 is a perspective view showing the display device according to the embodiment of the present disclosure when it is folded;

FIG. 5 is a cross-sectional view showing a display device according to an embodiment of the present disclosure;

FIG. 6 is a cross-sectional view showing an example of a display panel according to an embodiment of the present disclosure;

FIG. 7 is a plan view showing a panel support layer according to an embodiment of the present disclosure;

FIG. 8 is an enlarged view of area A of FIG. 7;

FIG. 9 is a plan view showing a lattice pattern of a panel support layer when a display device is folded according to an embodiment of the present disclosure;

FIG. 10 is a plan view showing a lattice pattern of a panel support layer according to Comparative Example;

FIG. 11 is a plan view showing the lattice pattern of the panel support layer according to Comparative Example when the display device is folded;

FIG. 12 is a plan view showing a lattice pattern of a panel support layer according to another embodiment of the present disclosure;

FIG. 13 is a plan view showing the lattice pattern of the panel support layer according to the embodiment of FIG. 12 when the display device is folded;

FIG. 14 is a plan view showing a lattice pattern of a panel support layer according to yet another embodiment of the present disclosure; and

FIG. 15 is a plan view showing a lattice pattern of a panel support layer according to yet another embodiment of the present disclosure.

### DETAILED DESCRIPTION OF THE EMBODIMENTS

The present disclosure will now be described in greater detail with reference to the accompanying drawings, which illustrate embodiments. This disclosure may, however, be embodied in different forms and should not be construed as limited to the embodiments set forth herein.

It will also be understood that when a layer is referred to as being “on” another layer or substrate, it can be directly on the other layer or substrate, or intervening layers may also be present. The same reference numbers indicate the same components throughout the specification.

This present disclosure relates to a foldable display device with an enhanced panel support layer designed to improve durability and flexibility during folding. The support layer includes a lattice pattern in the folding area, composed of alternating bars and slits, which allows controlled deformation while maintaining structural integrity. Additionally, cut lines positioned near the non-folding portions help evenly distribute mechanical stress, preventing concentrated strain that could lead to damage over time.

By optimizing the slit arrangement and incorporating cut lines, the present disclosure ensures smoother folding, reduced wear, and improved longevity of the display. The panel support layer can be made from metal plates (e.g., aluminum, stainless steel) or fiber-reinforced polymers, balancing flexibility with rigidity in key areas. This design minimizes issues like screen creasing and mechanical failure, making it ideal for next-generation foldable electronic devices.

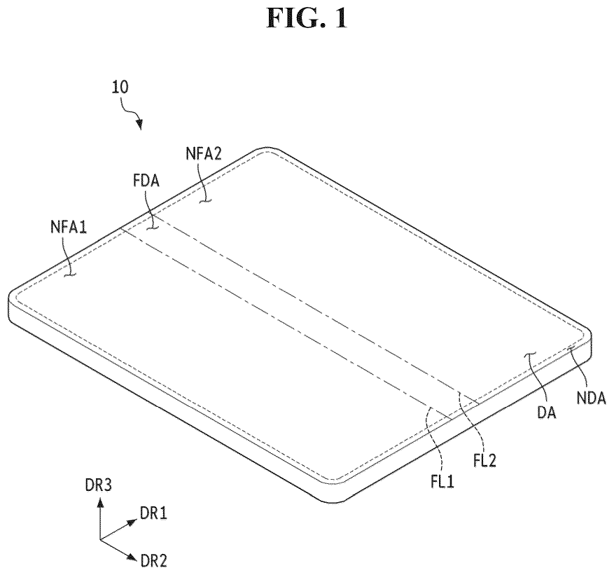

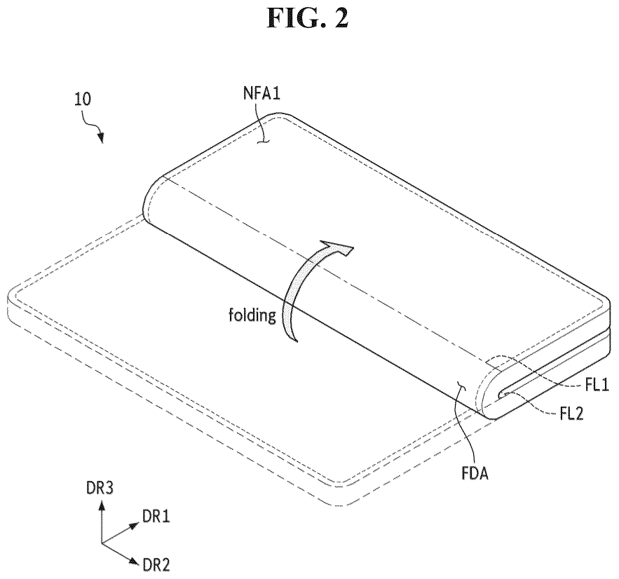

FIG. 1 is a perspective view showing a display device according to an embodiment of the present disclosure when it is unfolded. FIG. 2 is a perspective view showing the display device according to the embodiment of the present disclosure when it is folded.

Referring to FIGS. 1 and 2, FIG. 1 shows a first state in which the display device 10 is unfolded without being folded over the folding lines FL1 and FL2, and FIG. 2 shows a second state in which the display device 10 is folded over the folding lines FL1 and FL2.

According to the embodiment of the present disclosure, the display device 10 may be a foldable display device. According to the embodiment of the present disclosure, the display device 10 is applied to a smartphone. It should be understood, however, that the embodiments of the present disclosure are not limited thereto. For example, in the embodiment of the present disclosure, the display device 10 is configured to display both moving and still images. The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things.

The display device 10 according to the embodiments may be classified based on the method use to display images. For example, the display device 10 may include an organic light-emitting display device, an inorganic light-emitting display device, a quantum-dot light-emitting display device, a micro LED display device, a nano LED display device, a field emission display device, an electrophoretic display device, etc. In the following description, an organic light-emitting display device will be described as an example of the display device, and the organic light-emitting display device will be simply referred to as a display device unless it is necessary to discern it from others. It is, however, to be understood that the embodiments of the present disclosure are not limited to the organic light-emitting display device, and one of the above-listed display devices or any other display device known in the art may be employed without departing from the scope of the present disclosure.

In the drawings, the first direction DR1 may refer to a direction parallel to a side (e.g., a first side) of the display device 10, for example, the horizontal direction of the display device 10 when viewed from the top. A second direction DR2 may refer to a direction parallel to another side of the display device 10 that intersects with the side (e.g., the first side) of the display device 10, For example, when viewed from the top, DR2 may correspond to the vertical direction of the display device 10. A third direction DR3 may refer to the thickness direction of the display device 10.

The first direction DR1 and the second direction DR2 may be horizontal directions and may intersect each other. For example, the first direction DR1 and the second direction DR2 may be perpendicular to each other. In addition, a third direction DR3 may intersect the first direction DR1 and the second direction DR2, and may be a vertical direction, for example. Herein, the side indicated by the arrow of each of the first to third directions DR1, DR2 and DR3 may be referred to as a “first side,” while the opposite side may be referred to as an “opposite side,” unless state otherwise. As used herein, the terms “on,” “upper side,” “above,” “top” and “upper surface” refer to the side indicated by the arrow of the third direction DR3 as shown in the drawings. The terms “under,” “lower side,” “below,” “bottom” and “lower surface” refer to the opposite side indicated by the arrow of the third direction DR3 as shown in the drawings.

The display device 10 may have a rectangular shape or a square shape when viewed from the top. It should be understood, however, that the embodiments of the present disclosure are not limited thereto. In some embodiments, the display device 10 may have a rectangular shape with sharp corners or a rectangular shape with rounded corners when viewed from the top. The display device 10 may include two shorter sides extended in the first direction DR1 and two longer sides extended in the second direction DR2 when viewed from the top.

The display device 10 includes a display area DA and a non-display area NDA. The shape of the display area DA may conform to the shape of the display device 10 when viewed from the top. For example, if the display device 10 is rectangular when viewed from the top, the display area DA may also be rectangular.

The display area DA may include a plurality of pixels to display images. The plurality of pixels may be arranged in a matrix pattern. When viewed from the top, to plurality of pixels may take various shapes, including but not limited to rectangles, diamonds, or squares. For example, the plurality of pixels may also form a quadrangle other than a rectangle or diamond, a polygon other than a quadrangle, a circle, or an ellipse.

The non-display area NDA may not include pixels and thus may not display images. The non-display area NDA may be disposed around the display area DA. The non-display area NDA may be disposed to surround the display area DA as shown in FIGS. 1 and 2, but the present disclosure is not limited thereto. The display area DA may be partially surrounded by the non-display area NDA.

The display device 10 may stay either in a first state when it is unfolded or a second state when it is folded. The display device 10 may be folded inward (in an in-folding manner) so that the display area DA is located inside, as shown in FIG. 2. When the display device 10 is folded in the in-folding manner, a part of the front surface of the display device 10 may face another part of the front surface of the display device 10. Alternatively, the display device 10 may be folded outward (in an out-folding manner) so that the display area DA is located on the opposite sides and exposed to the outside. When the display device 10 is folded in the out-folding manner, a part of the rear surface of the display device 10 may face another part of the rear surface of the display device 10.

The display device 10 may include a folding area FDA, a first non-folding area NFA1, and a second non-folding area NFA2. The display device 10 can be bent or folded at the folding area FDA, while it cannot be bent or folded at the first non-folding area NFA1 and the second non-folding area NFA2. According to the embodiment, the first non-folding area NFA1 and the second non-folding area NFA2 may be flat areas of the display device 10. It should be understood, however, that the embodiments of the present disclosure are not limited thereto.

The first non-folding area NFA1 may be disposed on one side, for example, the left side of the folding area FDA. The second non-folding area NFA2 may be disposed on the opposite side, for example, the right side of the folding area FDA. Herein, the left side may refer to the second side in the first direction DR1, and the right side may refer to the first side in the first direction DR1.

The folding area FDA may be defined by the first folding line FL1 and the second folding line FL2, where the display device 10 can be bent with a predetermined curvature. The first folding line FL1 may be the boundary between the folding area FDA and the first non-folding area NFA1, and the second folding line FL2 may be the boundary between the folding area FDA and the second non-folding area NFA2.

As shown in FIGS. 1 and 2, the first folding line FL1 and the second folding line FL2 may be extended in the second direction DR2, and the display device 10 may be folded in the first direction DR1. Accordingly, the length of the display device 10 in the first direction DR1 can be reduced to about half, so that the display device 10 is easy to carry.

When the first folding line FL1 and the second folding line FL2 are extended in the second direction DR2, the length of the folding area FDA in the second direction DR2 may be larger than the length in the first direction DR1. In addition, the length of the first non-folding area NFA1 in the second direction DR2 may be larger than the length of the first non-folding area NFA1 in the first direction DR1. The length of the second non-folding area NFA2 in the second direction DR2 may be larger than the length of the second non-folding area NFA2 in the first direction DR1.

Each of the display area DA and the non-display area NDA may overlap at least one of the folding area FDA, the first non-folding area NFA1, and the second non-folding area NFA2. In the example shown in FIGS. 1 and 2, each of the display area DA and the non-display area NDA overlaps the folding area FDA, the first non-folding area NFA1 and the second non-folding area NFA2.

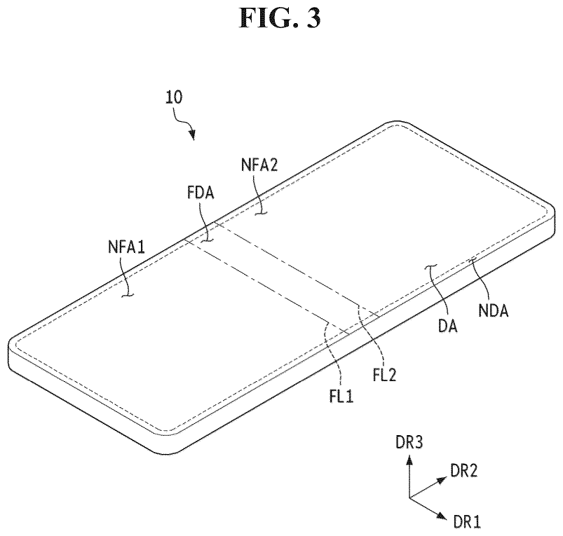

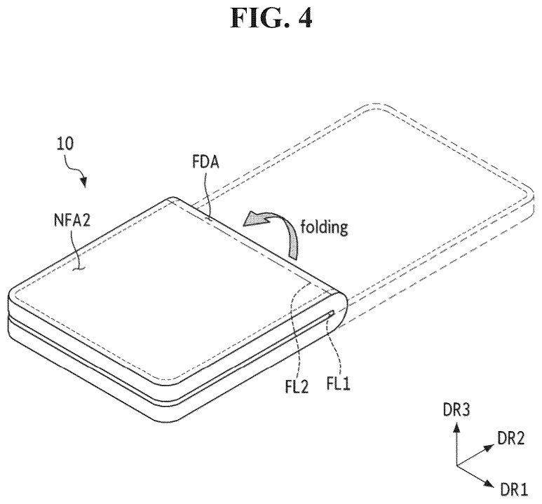

FIG. 3 is a perspective view showing a display device according to another embodiment of the present disclosure when it is unfolded. FIG. 4 is a perspective view showing the display device according to the embodiment of the present disclosure when it is folded.

Referring to FIGS. 3 and 4, FIG. 3 shows a first state in which the display device 10 is unfolded without being folded over the folding lines FL1 and FL2, and FIG. 4 shows a second state in which the display device 10 is folded over the folding lines FL1 and FL2.

In the first state in which the display device 10 is unfolded, the longer sides of the display device 10 may be extended in the second direction DR2, and the shorter sides of the display device 10 may be extended in the first direction DR1.

In the display device 10 according to the embodiment shown in FIGS. 3 and 4, the first folding line FL1 and the second folding line FL2 may be extended in the first direction DR1, and the display device 10 may be folded along the second direction DR2.

The first non-folding area NFA1 may be disposed on one side, for example, the lower side of the folding area FDA. The second non-folding area NFA2 may be disposed on the opposite side, for example, the upper side of the folding area FDA. Herein, the upper side may refer to the second side in the second direction DR2, and the lower side may refer to the first side in the second direction DR2.

As shown in FIGS. 3 and 4, when the first folding line FL1 and the second folding line FL2 are extended in the first direction DR1, the length of the folding area FDA in the first direction DR1 may be larger than the length in the second direction DR2. In addition, the length of the first non-folding area NFA1 in the second direction DR2 may be larger than the length of the first non-folding area NFA1 in the first direction DR1. The length of the second non-folding area NFA2 in the second direction DR2 may be larger than the length of the second non-folding area NFA2 in the first direction DR1.

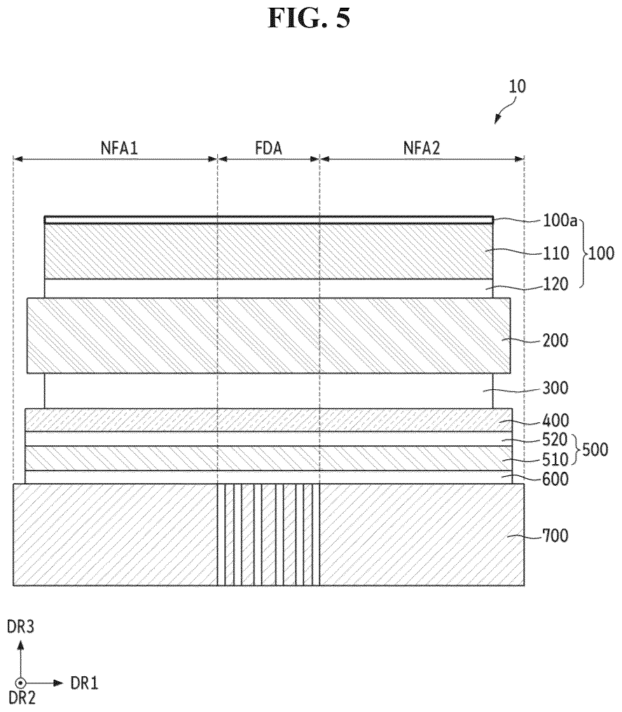

FIG. 5 is a cross-sectional view showing a display device according to an embodiment of the present disclosure.

Referring to FIG. 5, the display device 10 according to the embodiment may include an upper protective film 100, a window 200, a second adhesive layer 300, a display panel 400, a lower protective film 500, a fourth adhesive layer 600, and a panel support layer 700.

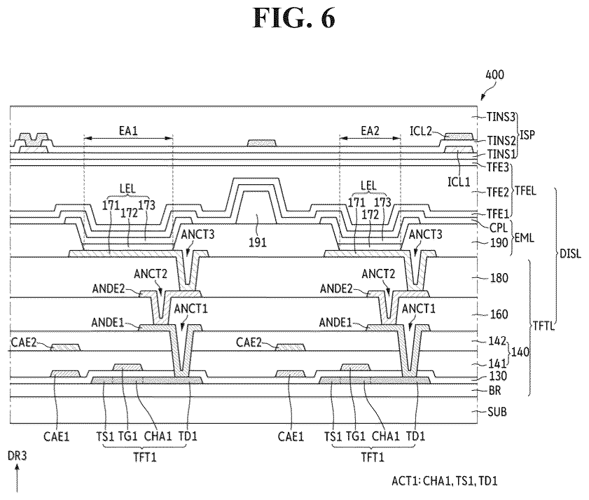

The display panel 400 may be a panel for displaying images. The display panel 400 may be an organic light-emitting display panel including an organic light-emitting layer, a quantum-dot light-emitting display panel including a quantum-dot light-emitting layer, an inorganic light-emitting display panel using an inorganic semiconductor element as a light-emitting element, and a micro light-emitting display panel using a micro light-emitting diode as a light-emitting element. In the following description, an organic light-emitting display panel is employed as the display panel 400. It is, however, to be understood that the present disclosure is not limited thereto. The display panel 400 will be described later with reference to FIG. 6.

The window 200 may be disposed on a surface of the display panel 400. For example, the window 200 may be disposed on the upper surface of the display panel 400. The window 200 can protect the display panel 400 from external shock. The window 200 can enhance the impact resistance of the display device 10.

The window 200 may be made of a transparent material. For example, the window 200 may be made of glass or plastic. In some embodiments, the window 200 may be ultra thin glass (UTG) having a thickness of 0.1 mm or less. Alternatively, the window 200 may be a transparent polyimide film.

The second adhesive layer 300 may be disposed under the window 200. For example, the second adhesive layer 300 may be disposed between the window 200 and the display panel 400. The window 200 and the display panel 400 may be coupled with each other by the second adhesive layer 300. The second adhesive layer 300 may include a transparent adhesive such as a pressure sensitive adhesive (PSA) and an optically clear adhesive (OCA). Alternatively, the second adhesive layer 300 may include an acrylic adhesive material.

The upper protective film 100 may be disposed on the window 200. The upper protective film 100 may include an upper protective layer 110, a coating film 100a, and a first adhesive layer 120.

The upper protective layer 110 may perform at least one of the following functions: shock absorption, scratch resistance, fingerprint resistance, glare reduction, and scattering prevention in the event of window 200 breakage. The upper protective layer 110 may include a material that is highly flexible and scratch-resistant. For example, the upper protective layer 110 may be a polymer film such as polyethylene terephthalate or a tempered glass film.

The coating film 100a may be disposed on the upper protective layer 110. For example, the coating film 100a may be disposed on the upper surface of the upper protective layer 110. The coating film 100a may be a low-reflection and anti-fingerprint (LRAF) coating film.

The first adhesive layer 120 may be disposed under the upper protective layer 110. For example, the first adhesive layer 120 may be disposed between the upper protective layer 110 and the window 200. The upper protective layer 110 and the window 200 may be coupled with each other by the first adhesive layer 120. The first adhesive layer 120 may include a transparent adhesive such as a pressure sensitive adhesive (PSA) and an optically clear adhesive (OCA). Alternatively, the first adhesive layer 120 may include an acrylic adhesive material.

The first adhesive layer 120 may remain attached to the upper protective layer 110 during the storage, transportation, and other handling processes of the upper protective film 100. Before the first adhesive layer 120 is attached to the window 200, a release film may be disposed on the lower surface of the first adhesive layer 120. The release film may be attached to the lower surface of the first adhesive layer 120 when handling the upper protective film 100 and may be removed when the first adhesive layer 120 is attached to the window 200.

The lower protective film 500 may be disposed on the opposite surface of the display panel 400. For example, the lower protective film 500 may be disposed on the lower surface of the display panel 400. The lower protective film 500 may include a lower protective layer 510 and a third adhesive layer 520.

The lower protective layer 510 may support the display panel 400 and protect the opposite surface of the display panel 400. According to some embodiments, the lower protective layer 510 may be plastic, such as polyethylene terephthalate (PET) and polyimide.

The third adhesive layer 520 may be disposed on the lower protective layer 510. For example, the third adhesive layer 520 may be disposed between the lower protective layer 510 and the display panel 400. The lower protective layer 510 and the display panel 400 may be coupled with each other by the third adhesive layer 520. The third adhesive layer 520 may include a transparent adhesive such as a pressure sensitive adhesive (PSA) and an optically clear adhesive (OCA). Alternatively, the third adhesive layer 520 may include an acrylic adhesive material.

The third adhesive layer 520 may remain attached to the lower protective layer 510 during the storage, transportation, and other handling processes of the lower protective film 500. Before the third adhesive layer 520 is attached to the display panel 400, a release film may be disposed on the upper surface of the third adhesive layer 520. The release film may be attached to the upper surface of the third adhesive layer 520 when handling the lower protective film 500 and may be removed when the third adhesive layer 520 is attached to the display panel 400.

The panel support layer 700 may be disposed under the lower protective film 500. The panel support layer 700 may be a rigid member that resists deformation or changes in volume under external pressure. Positioned on the opposite surface of the display panel 400, the panel support layer 700 provides structural support by maintaining its shape and volume, thereby reinforcing the display panel 400.

According to an embodiment of the present disclosure, the panel support layer 700 may be a metal plate. For example, the panel support layer 700 may be a metal plate and may be made of a metal or a metal alloy. The panel support layer 700 may include, but is not limited to, copper (Cu), aluminum (Al), stainless steel (SUS), and/or an alloy thereof.

According to another embodiment, the panel support layer 700 may be a polymer including carbon fiber or glass fiber. The panel support layer 700 may have a stack structure of polymer containing carbon fiber or glass fiber.

The panel support layer 700 may include a lattice pattern disposed on the folding area FDA so that it can be easily bent in the folding area FDA. Since the panel support layer 700 includes the lattice pattern disposed in the folding area FDA, it can bend more easily when the display device 10 is folded.

The fourth adhesive layer 600 may be disposed on the panel support layer 700. For example, the fourth adhesive layer 600 may be disposed between the panel support layer 700 and the lower protective film 500. The panel support layer 700 and the lower protective film 500 may be coupled with each other by the fourth adhesive layer 600. The fourth adhesive layer 600 may include a transparent adhesive such as a pressure sensitive adhesive (PSA) and an optically clear adhesive (OCA). Alternatively, the fourth adhesive layer 600 may include an acrylic adhesive material.

FIG. 6 is a cross-sectional view showing an example of a display panel according to an embodiment of the present disclosure.

Referring to FIG. 6, the display panel 400 may include a substrate SUB, a display layer DISL, and a touch sensor layer ISP. The display layer DISL may include a thin-film transistor layer TFTL, an emission material layer EML, and an encapsulation layer TFEL.

The substrate SUB may be made of an insulating material such as a polymer resin. For example, the substrate SUB may be made of polyimide. The substrate SUB may be a flexible substrate that can be bent, folded, or rolled.

The thin-film transistor layer TFTL may be disposed on the substrate SUB. The thin-film transistor layer TFTL may include a barrier layer BR, thin-film transistors TFT1, a first capacitor electrode CAE1, a second capacitor electrode CAE2, a first anode connection electrode ANDE1, a second anode connection electrode ANDE2, a gate insulator 130, a first interlayer dielectric film 141, a second interlayer dielectric film 142, a first planarization film 160, a second planarization film 180.

The barrier layer BR may be disposed on the substrate SUB. The barrier layer BR is a film for protecting the thin-film transistors of the thin-film transistor layer TFTL and an emissive layer 172 of the emission material layer EML. The barrier layer BR may be made up of multiple inorganic films stacked on one another alternately. For example, the barrier layer BR may be made up of multiple layers in which one or more inorganic layers of a silicon nitride layer, a silicon oxynitride layer, a silicon oxide layer, a titanium oxide layer and an aluminum oxide layer are alternately stacked on one another.

The thin-film transistors TFT1 may be disposed on the barrier layer BR. An active layer ACT1 of the thin-film transistor TFT1 may be disposed on the barrier layer BR. The active layer ACT1 of the thin-film transistor TFT1 may include polycrystalline silicon, monocrystalline silicon, low-temperature polycrystalline silicon, amorphous silicon, or an oxide semiconductor.

The active layer ACT1 may include a channel region CHA1, a source region TS1 and a drain region TD1. The channel region CHA1 may overlap with a gate electrode TG1 in the third direction DR3 that is the thickness direction of the substrate SUB. The source region TS1 may be disposed on one side of the channel region CHA1, and the drain region TD1 may be disposed on the opposite side of the channel region CHA1. The source region TS1 and the drain region TD1 may not overlap with the gate electrode TG1 in the third direction DR3. The source region TS1 and the drain region TD1 may be formed by doping a silicon semiconductor or an oxide semiconductor with ions or impurities to have conductivity.

The gate insulator 130 may be disposed on the active layer ACT1 of the thin-film transistor TFT1. The gate insulator 130 may be formed of an inorganic layer, for example, a silicon nitride layer, a silicon oxynitride layer, a silicon oxide layer, a titanium oxide layer, or an aluminum oxide layer.

The gate electrode TG1 of the thin-film transistor TFT1 and the first capacitor electrode CAE1 may be disposed on the gate insulator 130. The gate electrode TG1 may overlap with the channel region CHA1 in the third direction DR3. Although the gate electrode TG1 and the first capacitor electrode CAE1 are spaced apart from each other in the example shown in FIG. 6, the gate electrode TG1 and the first capacitor electrode CAE1 may be connected with each other as a single piece. The gate electrode TG1 and the first capacitor electrode CAE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric film 141 may be disposed on the gate electrode TG1 of the thin-film transistor TFT1 and the first capacitor electrode CAE1. The first interlayer dielectric film 141 may be formed of an inorganic layer, for example, a silicon nitride layer, a silicon oxynitride layer, a silicon oxide layer, a titanium oxide layer, or an aluminum oxide layer. The first interlayer dielectric film 141 may be made of a plurality of inorganic films.

The second capacitor electrode CAE2 may be disposed on the first interlayer dielectric film 141. The second capacitor electrode CAE2 may overlap the first capacitor electrode CAE1 of the thin-film transistor TFT1 in the third direction DR3. In addition, when the gate electrode TG1 and the first capacitor electrode CAE1 are integrally formed, the second capacitor electrode CAE2 may overlap the gate electrode TG1 in the third direction DR3. Since the first interlayer dielectric film 141 has a predetermined dielectric constant, a capacitor can be formed by the first capacitor electrode CAE1, the second capacitor electrode CAE2 and the first interlayer dielectric film 141 disposed therebetween. The second capacitor electrode CAE2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second interlayer dielectric film 142 may be disposed over the second capacitor electrode CAE2. The second interlayer dielectric film 142 may be formed of an inorganic layer, for example, a silicon nitride layer, a silicon oxynitride layer, a silicon oxide layer, a titanium oxide layer, or an aluminum oxide layer. The second interlayer dielectric film 142 may be made of a plurality of inorganic films.

The first interlayer dielectric film 141 and the second interlayer dielectric film 142 may be included in an interlayer dielectric film 140.

The first anode connection electrode ANDE1 may be disposed on the second interlayer dielectric film 142. The first anode connection electrode ANDE1 may be connected to the drain region TD1 of the thin-film transistor TFT1 through a first connection contact hole ANCT1 that penetrates the gate insulator 130, the first interlayer dielectric film 141 and the second interlayer dielectric film 142. The first anode connection electrode ANDE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first planarization film 160 may be disposed over the first anode connection electrode ANDE1 to create a flat surface, compensating for level differences caused by the thin-film transistor TFT1. The first planarization film 160 may be formed of an organic layer such as an acryl resin, an epoxy resin, a phenolic resin, a polyamide resin and a polyimide resin.

The second anode connection electrode ANDE2 may be disposed on the first planarization film 160. The second anode connection electrode ANDE2 may be connected to the first anode connection electrode ANDE1 through a second connection contact hole ANCT2 penetrating the first planarization film 160. The second anode connection electrode ANDE2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second planarization film 180 may be disposed on the second anode connection electrode ANDE2. The second planarization film 180 may be formed as an organic layer such as an acryl resin, an epoxy resin, a phenolic resin, a polyamide resin and a polyimide resin.

The emission material layer EML including light-emitting elements LEL and a bank 190 may be disposed on the second planarization film 180. Each of the light-emitting elements LEL includes a pixel electrode 171, an emissive layer 172, and a common electrode 173.

The pixel electrode 171 may be disposed on the second planarization film 180. The pixel electrode 171 may be connected to the second anode connection electrode ANDE2 through a third connection contact hole ANCT3 penetrating the second planarization film 180.

In the top-emission structure in which light exits from the emissive layer 172 toward the common electrode 173, the pixel electrode 171 may be made of a metal material having a high reflectivity such as a stack structure of aluminum and titanium (Ti/Al/Ti), a stack structure of aluminum (Al) and ITO (Indium Tin Oxide)/TO/Al/TO), an APC alloy and a stack structure of an APC alloy and ITO (ITO/APC/ITO). The APC alloy is an alloy of silver (Ag), palladium (Pd) and copper (Cu).

The bank 190 may partition the pixel electrode 171 on the second planarization film 180 to define a first emission area EA1 and a second emission area EA2. The bank 190 may be disposed to cover the edges of the pixel electrode 171. The bank 190 may be formed of an organic film such as an acryl resin, an epoxy resin, a phenolic resin, a polyamide resin and a polyimide resin.

In each of the first emission area EA1 and the second emission area EA2, the pixel electrode 171, the emissive layer 172 and the common electrode 173 are stacked on one another sequentially, so that holes from the pixel electrode 171 and electrons from the common electrode 173 are recombined with each other in the emissive layer 172 to emit light.

The emissive layer 172 may be disposed on the pixel electrode 171 and the bank 190. The emissive layer 172 may include an organic material to emit light of a certain color. For example, the emissive layer 172 may include a hole transporting layer, an organic material layer, and an electron transporting layer.

The common electrode 173 may be disposed on the emissive layer 172. The common electrode 173 may be disposed to cover the emissive layer 172. The common electrode 173 may be a common layer formed commonly across the first emission area EA1 and the second emission area EA2.

In the top-emission organic light-emitting diode, the common electrode 173 may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode 173 is formed of a semi-transmissive metal material, the light extraction efficiency can be increased by using microcavities.

A spacer 191 may be disposed on the bank 190. The spacer 191 may support a mask during a process of fabricating the emission layer 172. The spacer 191 may be formed of an organic layer such as an acryl resin, an epoxy resin, a phenolic resin, a polyamide resin and a polyimide resin.

According to some embodiments of the present disclosure, the display panel 400 may further include a capping layer CPL disposed on the common electrode 173. The capping layer CPL may be made of an inorganic material. For example, the capping layer CPL may include at least one of: silicon nitride, aluminum nitride, zirconium nitride, titanium nitride, hafnium nitride, tantalum nitride, silicon oxide, aluminum oxide, titanium oxide, tin oxide, cerium oxide and silicon oxynitride.

The encapsulation layer TFEL may be disposed on the common electrode 173. The encapsulation layer TFEL may include at least one inorganic layer to prevent permeation of oxygen or moisture into the emission material layer EML. In addition, the encapsulation layer TFEL may include at least one organic film to protect the emission material layer EML from particles such as dust. For example, the encapsulation layer TFEL may include a first inorganic encapsulation layer TFE1, an organic encapsulation layer TFE2 and a second inorganic encapsulation layer TFE3.

The first inorganic encapsulation layer TFE1 may be disposed on the common electrode 173, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation layer TFE2 may be an organic film such as an acryl resin, an epoxy resin, a phenolic resin, a polyamide resin, a polyimide resin, etc.

The touch sensor layer ISP may be disposed on the encapsulation layer TFEL. The touch sensor layer ISP may be mounted in the display panel 400 via continuous processes. The touch sensor layer ISP may include a first touch insulating film TINS1, a first conductive layer ICL1, a second touch insulating film TINS2, a second conductive layer ICL2, and a third touch insulating film TINS3.

The first touch insulating film TINS1 may be disposed on the encapsulation layer TFEL. The first touch insulating film TINS1 may be formed of an inorganic film, for example, a silicon nitride layer, a silicon oxynitride layer, a silicon oxide layer, a titanium oxide layer, or an aluminum oxide layer.

The first conductive layer ICL1 may be disposed on the first touch insulating film TINS1. The first conductive layer ICL1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The second touch insulating film TINS2 may be disposed on the first conductive layer ICL1. The second touch insulating film TINS2 may be formed of an inorganic layer, for example, a silicon nitride layer, a silicon oxynitride layer, a silicon oxide layer, a titanium oxide layer, or an aluminum oxide layer. Alternatively, the second touch insulating film TINS2 may be formed of an organic layer such as an acryl resin, an epoxy resin, a phenolic resin, a polyamide resin and a polyimide resin.

The second conductive layer ICL2 may be disposed on the second touch insulating film TINS2. The second conductive layer ICL2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A third touch insulating film TINS3 is formed on the second conductive layer ICL2. The third touch insulating film TINS3 may create a flat surface over the electrodes of the second conductive layer ICL2, compensating for variations in height. The third touch insulating film TINS3 may be formed of an organic layer such as an acryl resin, an epoxy resin, a phenolic resin, a polyamide resin and a polyimide resin.

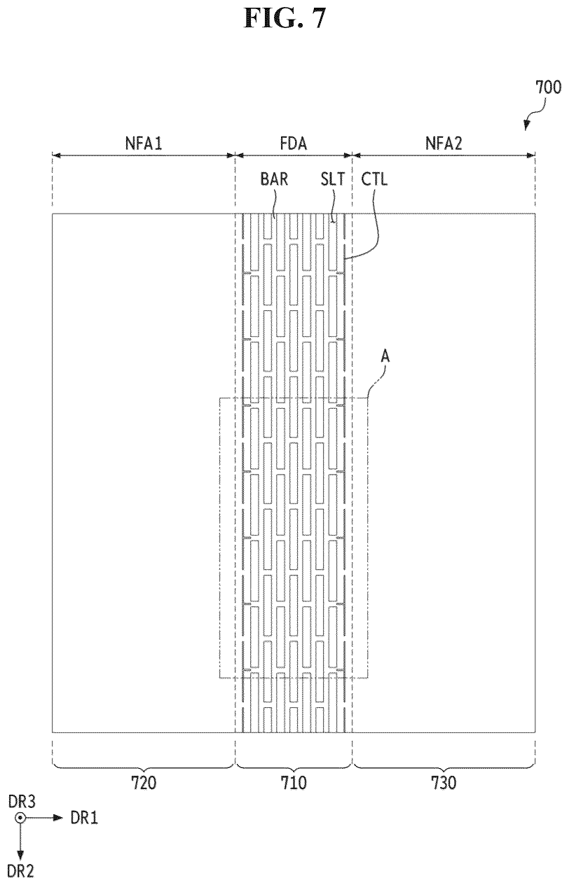

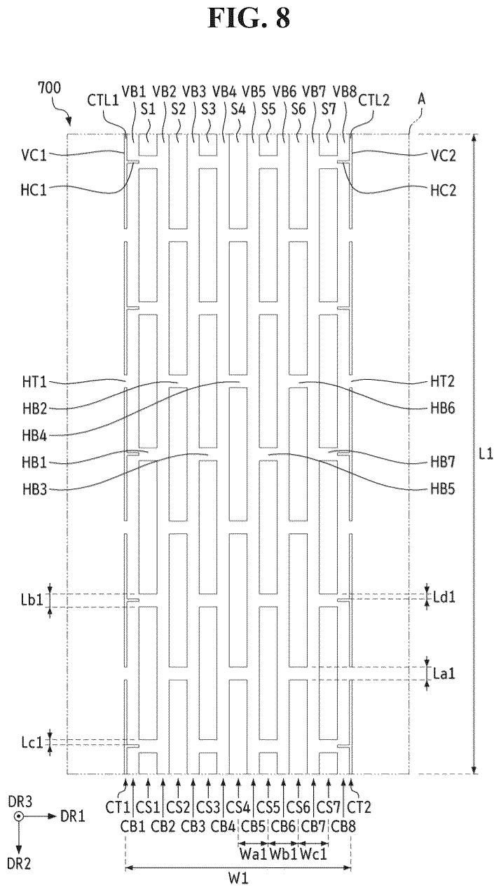

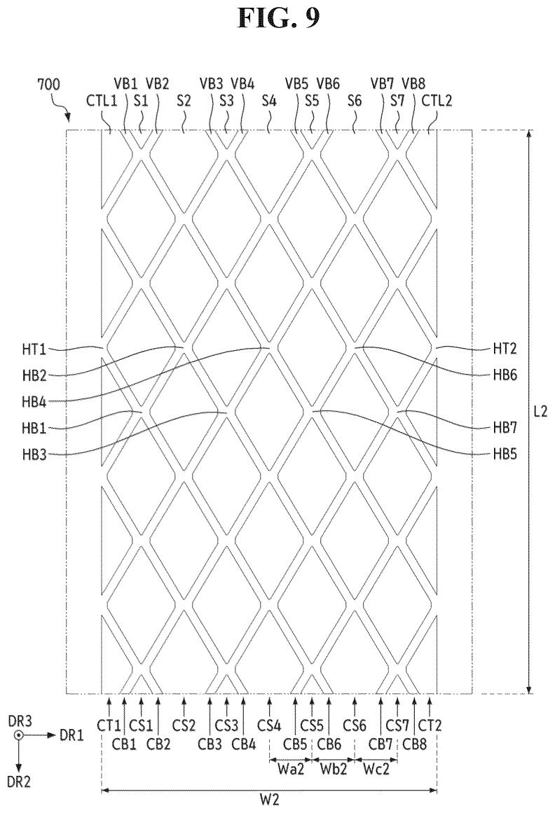

FIG. 7 is a plan view showing a panel support layer according to an embodiment of the present disclosure. FIG. 8 is an enlarged view of area A of FIG. 7. FIG. 9 is a plan view showing a lattice pattern of a panel support layer when a display device is folded according to an embodiment.

Referring to FIGS. 7 to 9, the panel support layer 700 may include a folding portion 710, a first non-folding portion 720 and a second non-folding portion 730. The folding portion 710 may be disposed in the folding area FDA, the first non-folding portion 720 may be disposed in the first non-folding area NFA1, and the second non-folding portion 730 may be disposed in the second non-folding area NFA2.

The first non-folding portion 720 and the second non-folding portion 730 may not be folded when the display device 10 is folded. The first non-folding portion 720 may be disposed on the second side of the folding portion 710 in the first direction DR1, and the second non-folding portion 730 may be disposed on the first side of the folding portion 710 in the first direction DR1.

The folding portion 710 may be folded when the display device 10 is folded. The folding portion 710 may be disposed between the first non-folding portion 720 and the second non-folding portion 730 in the first direction DR1.

The folding portion 710 may include a lattice pattern. For example, the folding portion 710 may include a plurality of bars BAR, and a plurality of slits SLT disposed between the plurality of bars BAR. Each of the plurality of slits SLT may be a hole penetrating the panel support layer 700 in the third direction DR3. The plurality of bars BAR may be solid portions of the panel support layer 700 where silts SLT are not present.

The slits SLT may be extended in the second direction DR2. For example, the length of each of the plurality of slits SLT in the second direction DR2 may be larger than its length in the first direction DR1.

In the example shown in FIG. 8, a lattice pattern includes a plurality of slits SLT arranged in first to seventh slit columns CS1 to CS7 and a plurality of bars BAR arranged in first to eighth bar columns CB1 to CB8. It should be noted that the number of the slit columns and the number of the bar columns are not limited thereto.

The first to seventh slit columns CS1 to CS7 and the first to eighth bar columns CB1 to CB8 may be arranged alternately in the first direction DR1. For example, the first to eighth bar columns CB1 to CB8 may be arranged in sequence in the first direction DR1. The first slit column CS1 may be disposed between the first bar column CB1 and the second bar column CB2, the second slit column CS2 may be disposed between the second bar column CB2 and the third bar column CB3, the third slit column CS3 may be disposed between the third bar column CB3 and the fourth bar column CB4, the fourth slit column CS4 may be disposed between the fourth bar column CB4 and the fifth bar column CB5, the fifth slit column CS5 may be disposed between the fifth bar column CB5 and the sixth bar column CB6, the sixth slit column CS6 may be disposed between the sixth bar column CB6 and the seventh bar column CB7, and the seventh slit column CS7 may be disposed between the seventh bar column CB7 and the eighth bar column CB8.

Each of the slits SLT in the first slit column CS1 may be referred to as a first slit S1, each of the slits SLT in the second slit column CS2 may be referred to as a second slit S2, each of the slits SLT in the third slit column CS3 may be referred to as a third slit S3, each of the slits SLT in the fourth slit column CS4 may be referred to as a fourth slit S4, each of the slits SLT in the fifth slit column CS5 may be referred to as a fifth slit S5, each of the slits SLT in the sixth slit column CS6 may be referred to as a sixth slit S6, and each of the slits SLT in the seventh slit column CS7 may be referred to as a seventh slit S7.

The plurality of bars BAR may include first to eighth vertical bars VB1 to VB8 and first to seventh horizontal bars HB1 to HB7.

Each of the bars BAR in the first bar column CB1 may be referred to as a first vertical bar VB1, each of the bars BAR in the second bar column CB2 may be referred to as a second vertical bar VB2, each of the bars BAR in the third bar column CB3 may be referred to as a third vertical bar VB3, each of the bars BAR in the fourth bar column CB4 may be referred to as a fourth vertical bar VB4, each of the bars BAR in the fifth bar column CB5 may be referred to as a fifth vertical bar VB5, each of the bars BAR in the sixth bar column CB6 may be referred to as a sixth vertical bar VB6, each of the bars BAR in the seventh bar column CB7 may be referred to as a seventh vertical bar VB7, and each of the bars BAR in the eighth bar column CB8 may be referred to as an eighth vertical bar VB8.

The first slit S1 may be located between the first vertical bar VB1 and the second vertical bar VB2, the second slit S2 may be located between the second vertical bar VB2 and the third vertical bar VB3, the third slit S3 may be located between the third vertical bar VB3 and the fourth vertical bar VB4, the fourth slit S4 may be located between the fourth vertical bar VB4 and the fifth vertical bar VB5, the fifth slit S5 may be located between the fifth vertical bar VB5 and the sixth vertical bar VB6, the sixth slit S6 may be located between the sixth vertical bar VB6 and the seventh vertical bar VB7, and the seventh slit S7 may be located between the seventh vertical bar VB7 and the eighth vertical bar VB8.

Each of the bars BAR in the first slit column CS1 may be referred to as a first horizontal bar HB1, each of the bars BAR in the second slit column CS2 may be referred to as a second horizontal bar HB2, each of the bars BAR in the third slit column CS3 may be referred to as a third horizontal bar HB3, each of the bars BAR in the fourth slit column CS4 may be referred to as a fourth horizontal bar HB4, each of the bars BAR in the fifth slit column CS5 may be referred to as a fifth horizontal bar HB5, each of the bars BAR in the sixth slit column CS6 may be referred to as a sixth horizontal bar HB6, and each of the bars BAR in the seventh slit column CS7 may be referred to as a seventh horizontal bar HB7.

The first horizontal bar HB1 may be disposed between first slits S1 that are adjacent to each other in the second direction DR2, the second horizontal bar HB2 may be disposed between second slits S2 that are adjacent to each other in the second direction DR2, the third horizontal bar HB3 may be disposed between third slits S3 that are adjacent to each other in the second direction DR2, the fourth horizontal bar HB4 may be disposed between fourth slits S4 that are adjacent to each other in the second direction DR2, the fifth horizontal bar HB5 may be disposed between fifth slits S5 that are adjacent to each other in the second direction DR2, the sixth horizontal bar HB6 may be disposed between sixth slits S6 that are adjacent to each other in the second direction DR2, and the seventh horizontal bar HB7 may be disposed between seventh slits S7 that are adjacent to each other in the second direction DR2.

The first horizontal bar HB1 may be disposed between the first vertical bar VB1 and the second vertical bar VB2 in the first direction DR1, the second horizontal bar HB2 may be disposed between the second vertical bar VB2 and the third vertical bar VB3 in the first direction DR1, the third horizontal bar HB3 may be disposed between the third vertical bar VB3 and the fourth vertical bar VB4 in the first direction DR1, the fourth horizontal bar HB4 may be disposed between the fourth vertical bar VB4 and the fifth vertical bar VB5 in the first direction DR1, the fifth horizontal bar HB5 may be disposed between the fifth vertical bar VB5 and the sixth vertical bar VB6 in the first direction DR1, the sixth horizontal bar HB6 may be disposed between the sixth vertical bar VB6 and the seventh vertical bar VB7, and the seventh horizontal bar HB7 may be disposed between the seventh vertical bar VB7 and the eighth vertical bar VB8 in the first direction DR1.

Among the first to seventh slits S1 to S7, the even-numbered slits S2, S4 and S6 may be shifted in the second direction DR2 relative to the odd-numbered slits S1, S3, S5 and S7. Accordingly, the lower ends of the odd-numbered slits S1, S3, S5 and S7 may overlap with the upper ends of the even-numbered slits S2, S4 and S6 at least partially in the first direction DR1. Additionally, the upper ends of the odd-numbered slits S1, S3, S5 and S7 may overlap with the lower ends of the even-numbered slits S2, S4 and S6 at least partially in the first direction DR1.

In addition, the odd-numbered horizontal bars HB1, HB3, HB5 and HB7 may be arranged in parallel in the first direction DR1, and the even-numbered horizontal bars HB2, HB4 and HB6 may be arranged in parallel in the first direction DR1. Moreover, the second horizontal bar HB2 may be disposed between the first slit S1 and the third slit S3, the third horizontal bar HB3 may be disposed between the second slit S2 and the fourth slit S4, the fourth horizontal bar HB4 may be disposed between the third slit S3 and the fifth slit S5, the fifth horizontal bar HB5 may be disposed between the fourth slit S4 and the sixth slit S6, and the sixth horizontal bar HB6 may be disposed between the fifth slit S5 and the seventh slit S7.

Since the folding portion 710 includes the lattice pattern with the plurality of slits SLT, it provides flexibility. When the display device 10 is folded as shown in FIG. 9, the lattice pattern extends in the first direction DR1 compared to its shape when the display device 10 is not folded as shown in FIG. 8. For example, upon folding, the lattice pattern may expand from a first width W1 to a second width W2 greater than the first width W1.

Furthermore, when the lattice pattern elongate in the first direction DR1 when the display device 10 is folded, the lattice pattern may simultaneously contract in the second direction DR2. For example, upon folding, the lattice pattern may shrink from a first length L1 to a second length L2 less than the first length L1.

The lattice pattern of the folding portion 710 of the display device 10 according to this embodiment may further include a plurality of cut lines CTL. Each of the plurality of cut lines CTL may be a hole penetrating the panel support layer 700 in the third direction DR3. According to some embodiments, the width of the plurality of cut lines CTL in the first direction DR1 may be smaller than the width of the plurality of slits SLT in the first direction DR1.

The plurality of cut lines CTL may include vertical cut lines VC1 and VC2 extended in the second direction DR2 and horizontal cut lines HC1 and HC2 extended in the first direction DR1. The length of each of the vertical cut lines VC1 and VC2 may be greater in the second direction DR2 than in the first direction DR1, while the length of each of the horizontal cut lines HC1 and HC2 may be greater in the first direction DR1 than in the second direction DR2.

The cut lines CTL may be disposed in a first outer column CT1 and a second outer column CT2. The first outer column CT1 may be located between the first bar column CB1 and the first non-folding portion 720, and the second outer column CT2 may be located between the eighth bar column CB8 and the second non-folding portion 730.

Each of the cut lines CTL disposed in the first outer column CT1 may be referred to as a first cut line CTL1, and each of the cut lines CTL disposed in the second outer column CT2 may be referred to as a second cut line CTL2.

The first cut lines CTL1 may include first vertical cut lines VC1 extended in the second direction DR2, and first horizontal cut lines HC1 extended in the first direction DR1, respectively. Each of the first horizontal cut lines HC1 may have a shape protruding in the first direction DR1 from the respective first vertical cut lines VC1. In other words, each first horizontal cut line HC1 may protrude in the first direction DR1 from its corresponding first vertical cut line VC1.

The second cut lines CTL2 may include second vertical cut lines VC2 extended in the second direction DR2, and second horizontal cut lines HC2 extended in the first direction DR1, respectively. Each of the second horizontal cut lines HC2 may have a shape protruding in the opposite direction to the first direction DR1 from the respective second vertical cut lines VC2. In other words, each second horizontal cut line HC2 may protrude in the direction opposite to the first direction DR1 from its corresponding second vertical cut line VC2.

The length of the first vertical cut line VC1 and the second vertical cut line VC2 in the second direction DR2 may be substantially equal to the length of the second slit S2, the fourth slit S4 and the sixth slit S6 in the second direction DR2. The first vertical cut line VC1 and the second vertical cut line VC2 may be positioned at the same locations in the second direction DR2 as the second slit S2, the fourth slit S4 and the sixth slit S6. For example, the first vertical cut line VC1 and the second vertical cut line VC2 may completely overlap with the second slit S2, the fourth slit S4 and the sixth slit S6 in the first direction DR1. In other words, the second slit S2, the fourth slit S4 and the sixth slit S6 may be disposed between the first vertical cut line VC1 and the second vertical cut line VC2 in the first direction DR1. The first vertical cut line VC1 and the second vertical cut line VC2 may be shifted in the second direction DR2 relative to the first slit S1, the third slit S3, the fifth slit S5 and the seventh slit S7.

In the second direction DR2, first spacing bars HT1 may be disposed between the first vertical cut lines VC1, and in the second direction DR2, second spacing bars HT2 may be disposed between the second vertical cut lines VC2. The first spacing bars HT1 and the second spacing bars HT2 may aligned with the second horizontal bars HB2, the fourth horizontal bars HB4 and the sixth horizontal bars HB6 in the first direction DR1. In other words, the first spacing bars HT1, the second spacing bars HT2, the second horizontal bars HB2, the fourth horizontal bars HB4 and the sixth horizontal bars HB6 may form a line in the first direction DR1. The length of the first spacing bars HT1 and the second spacing bars HT2 in the second direction DR2 may be equal to the length of the second horizontal bars HB2, the fourth horizontal bars HB4 and the sixth horizontal bars HB6. The length of the first spacing bars HT1 and the second spacing bars HT2 in the second direction DR2 may be referred to as a first subsidiary length La1.

The first horizontal cut lines HC1 may be located in the first bar column CB1. For example, the first horizontal cut lines HC1 may penetrate the first vertical bars VB1 in the second direction DR2. The second horizontal cut lines HC2 may be located in the eighth bar column CB8. For example, the second horizontal cut lines HC2 may penetrate the eighth vertical bars VB8 in the second direction DR2.

The first horizontal cut lines HC1 and the second horizontal cut lines HC2 may overlap with the first horizontal bar HB1, the third horizontal bar HB3, the fifth horizontal bar HB5 and the seventh horizontal bar HB7 in the first direction DR1. In other words, portions of the first horizontal bar HB1, the third horizontal bar HB3, the fifth horizontal bar HB5 and the seventh horizontal bar HB7 may be disposed between the first horizontal cut lines HC1 and the second horizontal cut lines HC2 in the first direction DR1. A distance Lc1 between the first horizontal cut lines HC1 and the first slits S1 in the second direction DR2 and a distance Ld1 between the second horizontal cut lines HC2 and the seventh slits S7 in the second direction DR2 may be less than a length Lb1 of the first horizontal bar HB1, the third horizontal bar HB3, the fifth horizontal bar HB5 and the seventh horizontal bar HB7.

According to this embodiment, the display device 10 includes the cut lines CTL, allowing the lattice pattern to evenly distribute tensile force for elongation in the first direction DR1 and contractile force for contraction in the second direction DR2.

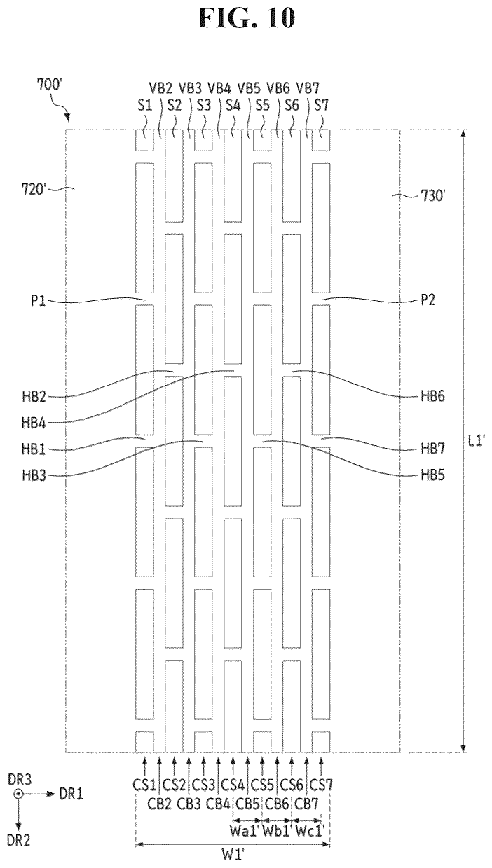

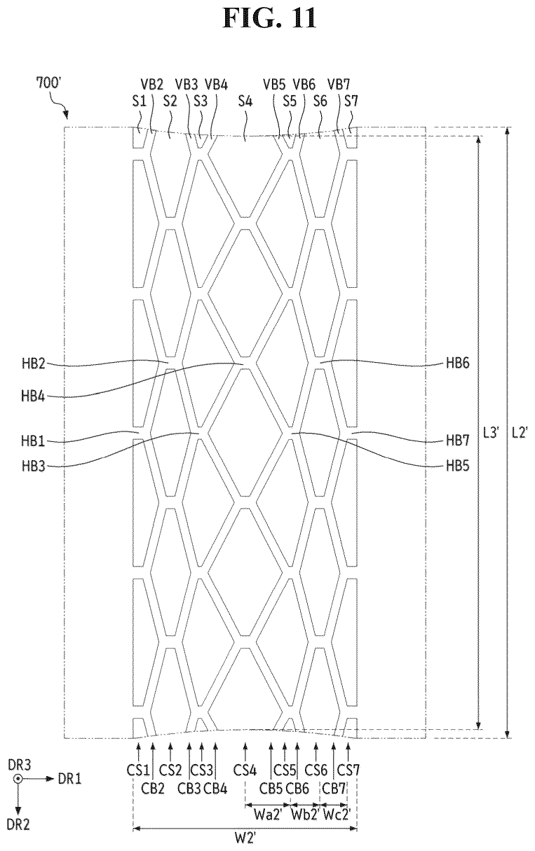

This will be further described by comparing it with a lattice pattern of another panel support layer according to Comparative Example of FIGS. 10 and 11.

FIG. 10 is a plan view showing a lattice pattern of a panel support layer according to Comparative Example. FIG. 11 is a plan view showing the lattice pattern of the panel support layer according to Comparative Example when the display device is folded.

Referring to FIGS. 10 and 11 in conjunction with FIGS. 7 to 9, a panel support layer 700′ according to Comparative Example may include a lattice pattern. The lattice pattern of the panel support layer 700′ according to Comparative Example is substantially identical to the lattice pattern of the panel support layer 700 described in the embodiment referenced to FIG. 8, etc., except that it does not include the cut lines CTL. Therefore, redundant descriptions will be omitted.

The lattice pattern of the panel support layer 700′ in the Comparative Example may elongate in the first direction DR1 when the display device 10 is folded, as shown in FIG. 11, compared to its shape when the display device 10 is not folded, as shown in FIG. 10. For example, upon folding, the lattice pattern of the panel support layer 700′ may expand from a first width W1′ to a second width W2′ greater than the first width W1′.

However, when the lattice pattern of the panel support layer 700′ in the Comparative Example elongates in the first direction DR1, it may exhibit minimal contraction in the second direction DR2. For example, when the display device 10 is folded, the edges of the lattice pattern of the panel support layer 700′, specifically the portions adjacent to the non-folding portions in the first direction DR1, may maintain a second length L2′ that is equal to a first length L1′.

The center of the lattice pattern (e.g., the center in the first direction DR1) of the panel support layer 700′ in the Comparative Example may contract from the first length L1′ to a third length L3′. The third length L3′ may be greater than the second length L2 of the lattice pattern of the panel support layer 700 described in the embodiment of FIGS. 7-9. In other words, the degree of contraction at the center of the lattice pattern of the panel support layer 700′ of the Comparative Example may be less than that of the lattice pattern of the panel support layer 700 described in the embodiment of FIGS. 7-9.

When the display device 10 is folded, the repulsive force in the lattice pattern of the panel support layer 700′ in the Comparative Example may be concentrated at first fixed portions P1 where the first horizontal bar HB1 meets the first non-folding portion 720′, and at second fixed portions P2 where the seventh horizontal bar HB7 meets the second non-folding portion 730′. Specifically, during folding, tensile force for elongation in the first direction DR1 and contractile force for contraction in the second direction DR2 are generated. However, in the lattice pattern of the panel support layer 700′ in the Comparative Example, the first fixed portion P1 and the second fixed portion P2 remain in contact with the first non-folding portion 720′ and the second non-folding portion 730′, respectively. As a result, the flexibility required for contraction in the second direction DR2 is insufficient, leading to a significant increase in the repulsive force.

As a result, the lattice pattern of the panel support layer 700′ in the Comparative Example may have different degrees of elongation in the first direction DR1 from the center to the edges in the second direction DR2. For example, when the display device 10 is unfolded, a distance Wa1′ between the center of the fourth horizontal bar HB4 and the center of the fifth horizontal bar HB5 in the second direction DR2, a distance Wb1′ between the center of the fifth horizontal bar HB5 and the center of the sixth horizontal bar HB6 in the second direction DR2, and a distance Wc1′ between the center of the sixth horizontal bar HB6 and the center of the seventh horizontal bar HB7 in the second direction DR2 may be substantially equal. On the other hand, when the display device 10 is folded, the distance Wa2′ between the center of the fourth horizontal bar HB4 and the center of the fifth horizontal bar HB5 in the second direction DR2 may be greater than the distance Wb2′ between the center of the fifth horizontal bar HB5 and the center of the sixth horizontal bar HB6 in the second direction DR2. Additionally, the distance Wb2′ between the center of the fifth horizontal bar HB5 and the center of the sixth horizontal bar HB6 in the second direction DR2 may be greater than the distance Wc2′ between the center of the sixth horizontal bar HB6 and the center of the seventh horizontal bar HB7 in the second direction DR2.

As such, the tensile force for elongation in the first direction DR1 and the contractile force for contraction in the second direction DR2 are not evenly distributed throughout the lattice pattern. Consequently, the first fixed portion P1 and/or the second fixed portion P2 may be subjected to excessive repulsive force, potentially leading to structural failure or cutting at these concentrated stress points.

In contrast, the lattice pattern of the panel support layer 700 in the embodiment of the present disclosure includes the cut lines CTL instead of the first fixed portion P1 and the second fixed portion P2. This design enables the lattice pattern to evenly distribute tensile force for elongation in the first direction DR1 and contractile force for contraction in the second direction DR2 when the display device 10 is folded, reducing the risk of stress concentration and structural failure.

Accordingly, the lattice pattern of the panel support layer 700 in the embodiment of the present disclosure may exhibit a uniform degree of elongation in the first direction DR1 at any point along the second direction DR2. For example, when the display device 10 is unfolded, a distance Wa1 between the center of the fourth horizontal bar HB4 and the center of the fifth horizontal bar HB5 in the second direction DR2, a distance Wb1 between the center of the fifth horizontal bar HB5 and the center of the sixth horizontal bar HB6 in the second direction DR2, and a distance Wc1 between the center of the sixth horizontal bar HB6 and the center of the seventh horizontal bar HB7 in the second direction DR2 may be substantially equal. In addition, when the display device 10 is folded, a distance Wa2 between the center of the fourth horizontal bar HB4 and the center of the fifth horizontal bar HB5 in the second direction DR2, a distance Wb2 between the center of the fifth horizontal bar HB5 and the center of the sixth horizontal bar HB6 in the second direction DR2, and a distance Wc2 between the center of the sixth horizontal bar HB6 and the center of the seventh horizontal bar HB7 in the second direction DR2 may be substantially equal.

In this manner, the tensile force for elongation in the first direction DR1 and the contractile force for contraction in the second direction DR2 can be evenly distributed throughout the lattice pattern, enhancing the durability of the panel support layer 700.

Hereinafter, display devices according to other embodiments of the present disclosure will be described. In the following description, the same or similar elements will be denoted by the same or similar reference numerals, and redundant descriptions will be omitted or briefly described.

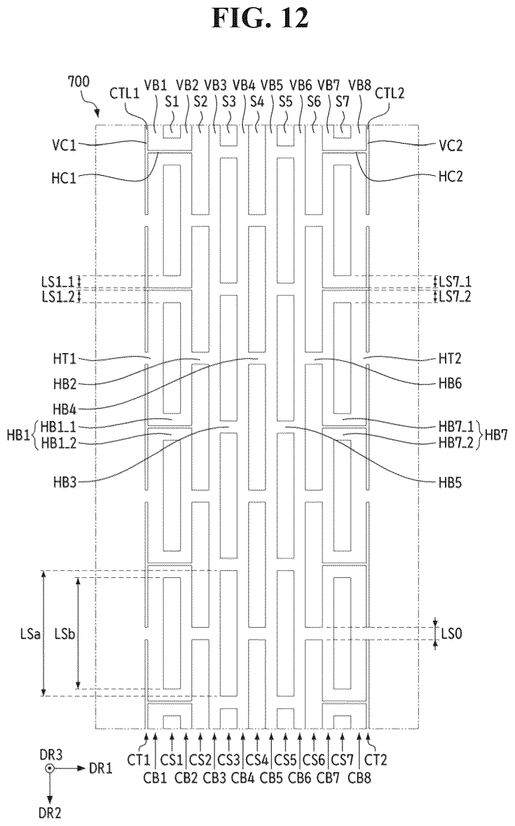

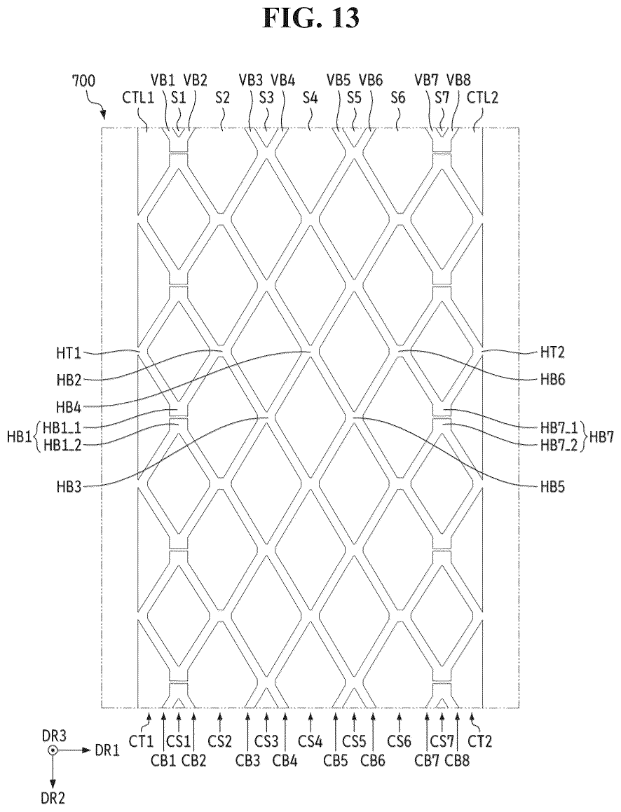

FIG. 12 is a plan view showing a lattice pattern of a panel support layer according to another embodiment of the present disclosure. FIG. 13 is a plan view showing the lattice pattern of the panel support layer according to the embodiment of FIG. 12 when the display device is folded.

A display device 10 according to the embodiment of FIGS. 12 and 13 is different from the display device 10 according to the above-described embodiment of FIG. 8, etc., in that the shape of the horizontal cut lines HC1 and HC2 is different.

More specifically, in the display device 10 according to this embodiment, the horizontal cut lines HC1 and HC2 may be connected with the slits SLT. For example, the first horizontal cut lines HC1 may be connected with the second slits S2, and the second horizontal cut lines HC2 may be connected with the sixth slits S6. For example, the first cut line CTL1 may be connected with the second slits S2, and the second cut line CTL2 may be connected with the sixth slits S6. In this case, an individual second slit S2, an individual first horizontal cut line HC1 and an individual first cut line CTL1 may together form a single opening in the panel support layer 700. Similarly, an individual sixth slit S6, an individual second horizontal cut line HC2 and an individual second cut line CTL2 may together form a single opening in the panel support layer 700.

The first horizontal cut lines HC1 may be extended in the first direction DR1 and may be located in the first bar column CB1, the first slit column CS1 and the second bar column CB2. The first horizontal cut lines HC1 may be located between the first slits S1 in the second direction DR2.

The first horizontal bar HB1 may be divided into two parts by the first horizontal cut line HC1. For example, the first horizontal bar HB1 may include a first sub-horizontal bar HB1_1 and a second sub-horizontal bar HB1_2. The first sub-horizontal bar HB1_1 and the second sub-horizontal bar HB1_2 may be positioned on opposite sides with the first horizontal cut line HC1 therebetween. The first sub-horizontal bar HB1_1 may be disposed on the second side of the first horizontal cut line HC1 in the second direction DR2, and the second sub-horizontal bar HB1_2 may be disposed on the first side of the first horizontal cut line HC1 in the second direction DR2.

The second horizontal cut lines HC2 may be extended in the first direction DR1 and may be located in the eighth bar column CB8, the seventh slit column CS7 and the seventh bar column CB7. The second horizontal cut lines HC2 may be located between the seventh slits S7 in the second direction DR2.

The second horizontal bar HB7 may be divided into two parts by the second horizontal cut line HC2. For example, the seventh horizontal bar HB7 may include a third sub-horizontal bar HB7_1 and a fourth sub-horizontal bar HB7_2. The third sub-horizontal bar HB7_1 and the fourth sub-horizontal bar HB7_2 may be positioned on opposite sides with the second horizontal cut line HC2 therebetween. The third sub-horizontal bar HB7_1 may be disposed on the second side of the second horizontal cut line HC2 in the second direction DR2, and the fourth sub-horizontal bar HB7_2 may be disposed on the first side of the second horizontal cut line HC2 in the second direction DR2.

According to some embodiments, a length LSa of the first slit S1 and the seventh slit S7 in the second direction DR2 may be smaller than a length LSb of the third slit S3 and the fifth slit S5 in the second direction DR2. A length LS1_1 of the first sub-horizontal bar HB1_1 in the second direction DR2, a length LS1_2 of the second sub-horizontal bar HB1_2 in the second direction DR2, a length LS7_1 of the third sub-horizontal bar HB7_1 in the second direction DR2 and a length LS7_2 of the fourth sub-horizontal bar HB7_2 in the second direction DR2 may be substantially equal to a length LS0 of the second to sixth slits S2 to S6 in the second direction DR2.

Accordingly, by maintaining a constant width for the bars BAR adjacent to the slits SLT, the tensile force for elongation in the first direction DR1 and the contractile force for contraction in the second direction DR2 can be more evenly distributed when the display device 10 is folded.

Although the length of the first slit S1 and the seventh slit S7 in the second direction DR2 is equal to the length of the third slit S3 and the fifth slit S5 in the display device 10 according to the embodiment described above with reference to FIG. 8, etc., it is to be understood that the present disclosure is not limited thereto. For example, like the display device 10 according to the embodiment described above with reference to FIG. 12, the length of the first slit S1 and the seventh slit S7 in the second direction DR2 may be smaller than the length of the third slit S3 and the fifth slit S5 in the second direction DR2. Accordingly, the distance Lc1 between the first horizontal cut lines HC1 and the first slits S1 in the second direction DR2 and the distance Ld1 between the second horizontal cut lines HC2 and the seventh slits S7 in the second direction DR2 may be substantially equal to the length Lb1 of the first horizontal bar HB1, the third horizontal bar HB3, the fifth horizontal bar HB5 and the seventh horizontal bar HB7.

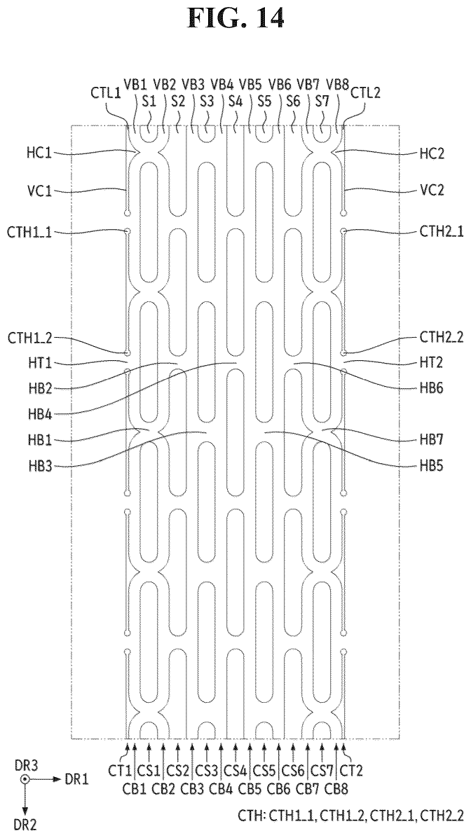

FIG. 14 is a plan view showing a lattice pattern of a panel support layer according to yet another embodiment of the present disclosure.

A display device 10 according to the embodiment of FIG. 14 is different from the display device 10 according to the embodiment described above with reference to FIG. 8, etc., in that the shape of the slits SLT is different and cut holes CTH are further included.

More specifically, a plurality of slits SLT in the display device 10 according to this embodiment may have rounded ends in the second direction DR2. Accordingly, the horizontal cut lines HC1 and HC2 may include curves conforming to the shape of the both ends of the plurality of slits SLT. Since the slits SLT have the rounded ends, the tensile force for elongation in the first direction DR1 and the contractile force for contraction in the second direction DR2 can be more evenly distributed when the display device 10 is folded.

According to some embodiments, the cut lines CTL may further include cut holes CTH. For example, a first cut line CTL1 may include a first cut hole CTH1_1 and a second cut hole CTH1_2, and a second cut line CTL2 may include a third cut hole CTH2_1 and a fourth cut hole CTH2_2. As shown in FIG. 14, the shape of the cut holes CTH may be, but is not limited to, circular when viewed from the top. The shape of the cut holes CTH when viewed from the top may be modified in a variety of ways.

The first cut hole CTH1_1 and the second cut hole CTH1_2 may be formed at the both ends of the first vertical cut line VC1 in the second direction DR2, respectively. For example, the first cut hole CTH1_1 may be formed on the second side of the first vertical cut line VC1 in the second direction DR2, and the second cut hole CTH1_2 may be formed on the first side of the first vertical cut line VC1 in the second direction DR2.

The third cut hole CTH2_1 and the fourth cut hole CTH2_2 may be formed at the both ends of the second vertical cut line VC2 in the second direction DR2, respectively. For example, the third cut hole CTH2_1 may be formed on the second side of the second vertical cut line VC2 in the second direction DR2, and the fourth cut hole CTH2_2 may be formed on the first side of the second vertical cut line VC2 in the second direction DR2.

Although the cut holes CTH are formed at the both ends of the first vertical cut line VC1 and the both ends of the second vertical cut line VC2 in FIG. 14, the present disclosure is not limited thereto. For example, the first cut line CTL1 may not include one of the first cut hole CTH1_1 and the second cut hole CTH1_2, and the second cut line CTL2 may not include one of the third cut hole CTH2_1 and the fourth cut hole CTH2_2.

According to this embodiment, the display device 10 includes the cut holes CTH, which allow the tensile force for elongation in the first direction DR1 and the contractile force for contraction in the second direction DR2 to be evenly distributed when the display device 10 is folded.

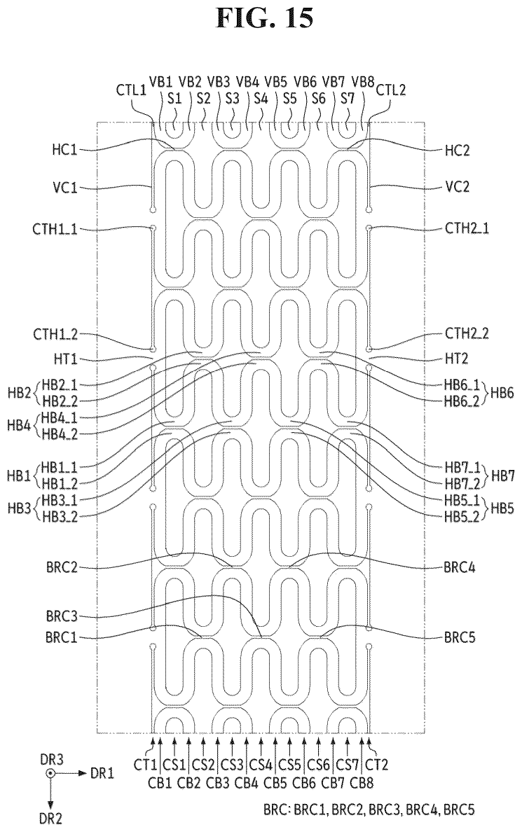

FIG. 15 is a plan view showing a lattice pattern of a panel support layer according to yet another embodiment of the present disclosure.

The display device 10 according to this embodiment of FIG. 15 is different from the display device 10 according to the embodiment of FIG. 14, etc., in that the shape of horizontal cut lines HC1 and HC2 is different, and bridge cut lines BRC are further included.

More specifically, in the display device 10 according to this embodiment, the horizontal cut lines HC1 and HC2 may be connected with the slits SLT. For example, the first horizontal cut lines HC1 may be connected with the second slits S2, and the second horizontal cut lines HC2 may be connected with the sixth slits S6. For example, the first cut line CTL1 may be connected with the second slits S2, and the second cut line CTL2 may be connected with the sixth slits S6.

The display device 10 according to this embodiment may further include bridge cut lines BRC. The bridge cut lines BRC may include a first bridge cut line BRC1, a second bridge cut line BRC2, a third bridge cut line BRC3, a fourth bridge cut line BRC4 and a fifth bridge cut line BRC5.

The first to seventh slits S1 to S7 may be connected with one another by the bridge cut lines BRC. For example, the first slit S1 and the third slit S3 may be connected with each other by the first bridge cut line BRC1, the second slit S2 and the fourth slit S4 may be connected with each other by the second bridge cut line BRC2, the third slit S3 and the fifth slit S5 may be connected with each other by the third bridge cut line BRC3, the fourth slit S4 and the sixth slit S6 may be connected with each other by the fourth bridge cut line BRC4, and the fifth slit S5 and the seventh slit S7 may be connected with each other by the fifth bridge cut line BRC5.

The first horizontal cut lines HC1 may be extended in the first direction DR1 and may be located in the first bar column CB1, the first slit column CS1 and the second bar column CB2. The first horizontal cut lines HC1 may be located between the first slits S1 in the second direction DR2.

The first horizontal bar HB1 may be divided into two parts by the first horizontal cut line HC1. For example, the first horizontal bar HB1 may include a first sub-horizontal bar HB1_1 and a second sub-horizontal bar HB1_2. The first sub-horizontal bar HB1_1 and the second sub-horizontal bar HB1_2 may be positioned on opposite sides with the first horizontal cut line HC1 therebetween. The first sub-horizontal bar HB1_1 may be disposed on the second side of the first horizontal cut line HC1 in the second direction DR2, and the second sub-horizontal bar HB1_2 may be disposed on the first side of the first horizontal cut line HC1 in the second direction DR2.

The first bridge cut lines BRC1 may be extended in the first direction DR1 and may be located in the second bar column CB2, the second slit column CS2 and the third bar column CB3. The first bridge cut lines BRC1 may be located between the second slits S2 in the second direction DR2. For example, the first bridge cut line BRC1 may separate two adjacent second slits S2 in the second direction DR2 from each other.

The second horizontal bar HB2 may be divided into two parts by the first bridge cut line BRC1. For example, the second horizontal bar HB2 may include a third sub-horizontal bar HB2_1 and a fourth sub-horizontal bar HB2_2. The third sub-horizontal bar HB2_1 and the fourth sub-horizontal bar HB2_2 may be positioned on opposite sides with the first bridge cut line BRC1 therebetween. The third sub-horizontal bar HB2_1 may be disposed on the second side of the first bridge cut line BRC1 in the second direction DR2, and the fourth sub-horizontal bar HB2_2 may be disposed on the first side of the first bridge cut line BRC1 in the second direction DR2.

The second bridge cut line BRC2 may be extended in the first direction DR1 and may be located in the third bar column CB3, the third slit column CS3 and the fourth bar column CB4. The second bridge cut lines BRC2 may be located between the third slits S3 in the second direction DR2. The second bridge cut line BRC2 may separate two adjacent third slits S3 in the second direction DR2 from each other.

The third horizontal bar HB3 may be divided into two parts by the second bridge cut line BRC2. For example, the third horizontal bar HB3 may include a fifth sub-horizontal bar HB3_1 and a sixth sub-horizontal bar HB3_2. The fifth sub-horizontal bar HB3_1 and the sixth sub-horizontal bar HB3_2 may be positioned on the opposite sides with the second bridge cut line BRC2 therebetween. The fifth sub-horizontal bar HB3_1 may be disposed on the second side of the second bridge cut line BRC2 in the second direction DR2, and the sixth sub-horizontal bar HB3_2 may be disposed on the first side of the second bridge cut line BRC2 in the second direction DR2.

The third bridge cut lines BRC3 may be extended in the first direction DR1 and may be located in the fourth bar column CB4, the fourth slit column CS4 and the fifth bar column CB5. The third bridge cut lines BRC3 may be located between the fourth slits S4 in the second direction DR2. For example, the third bridge cut line BRC3 may separate two adjacent fourth slits S4 in the second direction DR2 from each other.

The fourth horizontal bar HB4 may be divided into two parts by the third bridge cut line BRC3. For example, the fourth horizontal bar HB4 may include a seventh sub-horizontal bar HB4_1 and an eighth sub-horizontal bar HB4_2. The seventh sub-horizontal bar HB4_1 and the eighth sub-horizontal bar HB5_2 may be positioned on the opposite sides with the third bridge cut line BRC3 therebetween. The seventh sub-horizontal bar HB4_1 may be disposed on the second side of the third bridge cut line BRC3 in the second direction DR2, and the eighth sub-horizontal bar HB4_2 may be disposed on the first side of the third bridge cut line BRC3 in the second direction DR2.

The fourth bridge cut lines BRC4 may be extended in the first direction DR1 and may be located in the fifth bar column CB5, the fifth slit column CS5 and the sixth bar column CB6. The fourth bridge cut lines BRC4 may be located between the fifth slits S5 in the second direction DR2. For example, the fourth bridge cut line BRC4 may separate two adjacent fifth slits S5 in the second direction DR2 from each other.

The fifth horizontal bar HB5 may be divided into two parts by the fourth bridge cut line BRC4. For example, the fifth horizontal bar HB5 may include a ninth sub-horizontal bar HB5_1 and a tenth sub-horizontal bar HB5_2. The ninth sub-horizontal bar HB5_1 and the tenth sub-horizontal bar HB5_2 may be positioned on the opposite sides with the fourth bridge cut line BRC4 therebetween. The ninth sub-horizontal bar HB5_1 may be disposed on the second side of the fourth bridge cut line BRC4 in the second direction DR2, and the tenth sub-horizontal bar HB5_2 may be disposed on the first side of the fourth bridge cut line BRC4 in the second direction DR2.

The fifth bridge cut lines BRC5 may be extended in the first direction DR1 and may be located in the sixth bar column CB6, the second slit column CS6 and the seventh bar column CB7. The fifth bridge cut lines BRC5 may be located between the sixth slits S6 in the second direction DR2. For example, the fifth bridge cut line BRC5 may separate two adjacent sixth slits S6 in the second direction DR2 from each other.

The sixth horizontal bar HB6 may be divided into two parts by the fifth bridge cut line BRC5. For example, the sixth horizontal bar HB6 may include an eleventh sub-horizontal bar HB6_1 and a twelfth sub-horizontal bar HB6_2. The eleventh sub-horizontal bar HB6_1 and the twelfth sub-horizontal bar HB6_2 may be positioned on the opposite sides with the fifth bridge cut line BRC5 therebetween. The eleventh sub-horizontal bar HB6_1 may be disposed on the second side of the fifth bridge cut line BRC5 in the second direction DR2, and the twelfth sub-horizontal bar HB6_2 may be disposed on the first side of the fifth bridge cut line BRC5 in the second direction DR2.

The second horizontal cut lines HC2 may be extended in the first direction DR1 and may be located in the eighth bar column CB8, the seventh slit column CS7 and the seventh bar column CB7. The second horizontal cut lines HC2 may be located between the seventh slits S7 in the second direction DR2.

The second horizontal bar HB7 may be divided into two parts by the second horizontal cut line HC2. For example, the seventh horizontal bar HB7 may include a thirteenth sub-horizontal bar HB7_1 and a fourteenth sub-horizontal bar HB7_2. The thirteenth sub-horizontal bar HB7_1 and the fourteenth sub-horizontal bar HB7_2 may be positioned on opposite sides with the second horizontal cut line HC2 therebetween. The thirteenth sub-horizontal bar HB7_1 may be disposed on the second side of the second horizontal cut line HC2 in the second direction DR2, and the fourteenth sub-horizontal bar HB7_2 may be disposed on the first side of the second horizontal cut line HC2 in the second direction DR2.

In the display device 10 according to this embodiment, the slits SLT and the cut lines CTL may be connected with each other by the horizontal cut lines HC1 and HC2 and the bridge cut lines BRC. For example, the first slit S1, the third slit S3, the fifth slit S5 and the seventh slit S7 may be connected with one another by the first bridge cut line BCR1, the third bridge cut line BRC3 and the fifth bridge cut line BRC5. The first vertical cut line VC1, the second slit S2, the fourth slit S4, the sixth slit S6 and the second vertical cut line VC2 may be connected with each other by the first horizontal cut line HC1, the second bridge cut line BCR1, the fourth bridge cut line BRC5 and the second horizontal cut line HC2.

According to this embodiment, the display device 10 includes the bridge cut lines BRC, so that the tensile force for elongation in the first direction DR1 and the contractile force for contraction in the second direction DR2 can be evenly distributed when the display device 10 is folded.

Additionally, the display devices 10 according to the embodiments described above with reference to FIGS. 8, 12, 14, etc., may also further include bridge cut lines BRC. In this case, similar to the display device 10 described in the embodiment referenced in FIG. 15, the horizontal bars BAR may be divided into sub-horizontal bars BAR that are disposed on the both sides of the bridge cut lines BRC and spaced apart from each other by the bridge cut lines BRC.

In conclusion, those skilled in the art will recognize that many variations and modifications can be made to the described embodiments without substantially departing from the principles of the present disclosure. Therefore, the embodiments described herein are intended to be illustrative and descriptive, rather than restrictive.

1. A display device comprising:
a display panel; and
a panel support layer disposed on the display panel,
wherein the panel support layer comprises:
a folding portion,
at least one non-folding portion disposed on at least one side of the folding portion,
a plurality of bars and a plurality of slits alternately arranged at the folding portion, and
at least one cut line disposed between the slits and the non-folding portion.

2. The display device of claim 1, wherein a width of the cut line is smaller than a width of one of the plurality of slits.

3. The display device of claim 1, wherein the at least one cut line comprises a first cut line and a second cut line,
wherein the first cut line is disposed between the plurality of slits and the non-folding portion, and
wherein the second cut line is extended from the first cut line toward the plurality of slits.

4. The display device of claim 3, wherein the first cut line is extended in a same direction as an extension direction of the plurality of slits, and
wherein the second cut line is extended in a different direction from the extension direction of the plurality of slits.

5. The display device of claim 3, wherein the first cut line further comprises a cut hole formed at least one end of the first cut line.

6. The display device of claim 1, wherein the plurality of slits comprises first slits arranged in a first column, second slits arranged in a second column, and third slits arranged in a third column, and
wherein the second slits are offset in a direction relative to the first slits and the third slits.

7. The display device of claim 6, wherein the cut line is parallel to the second slits and is offset in the direction relative to the first slits and the third slits.

8. The display device of claim 7, wherein the at least one cut line comprises a first cut line extended in the direction relative to the first slits and the third slits and a second cut line extended from the first cut line toward the plurality of slits, and
wherein a distance between the second cut line and the first slits in the direction relative to the first slits and the third slits is smaller than a distance between the first slits.

9. The display device of claim 7, wherein the at least one cut line comprises a first cut line extended in the direction relative to the first slits and the third slits and a second cut line extended from the first cut line toward the plurality of slits, and
wherein a distance between the second cut line and the first slits in the direction relative to the first slits and the third slits is equal to a distance between the first slits.

10. The display device of claim 7, wherein the at least one cut line comprises a plurality of cut lines,
wherein the cut lines are spaced apart from each other in the direction relative to the first slits and the third slits, and
wherein the bars comprise spaced bars that are arranged between the cut lines.

11. The display device of claim 10, wherein a spacing between the cutting lines is equal to a spacing between the second slits.

12. The display device of claim 6, wherein the slits are extended in a direction different from the direction relative to the first slits and the third slits when the display panel is folded, and
wherein lengths of the first to third slits are equal to one another.

13. The display device of claim 12, wherein the slits contract in the direction relative to the first slits and the third slits when the display panel is folded.

14. The display device of claim 6, wherein the at least one cut line comprises a first cut line extended in the direction relative to the first slits and the third slits and a second cut line extended from the first cut line toward the plurality of slits, and
wherein the second cut line is connected with the second slits.

15. The display device of claim 14, wherein the second cut line is located between the first slits in the direction relative to the first slits and the third slits.

16. The display device of claim 15, wherein a length of the first slits in the direction relative to the first slits and the third slits is smaller than a length of the third slits in the direction relative to the first slits and the third slits.

17. The display device of claim 14, wherein the plurality of bars comprises first horizontal bars disposed between the first slits, and
wherein the first horizontal bars comprise a first sub-horizontal bar and a second sub-horizontal bar spaced apart from each other with the second cut line therebetween.

18. A display device comprising:
a display panel; and
a panel support layer disposed on the display panel,
wherein the panel support layer comprises:
a folding portion,
a first non-folding portion disposed on a first side of the folding portion,
a second non-folding portion disposed on a second side of the folding portion, and
a lattice pattern disposed in the folding portion, and
wherein the lattice pattern comprises:
a plurality of bars and a plurality of slits alternately arranged,
a first cut line disposed between the plurality of slits and the first non-folding portion, and
a second cut line disposed between the plurality of slits and the second non-folding portion.

19. The display device of claim 18, wherein a width of one of the cut lines is smaller than a width of one of the plurality of slits.

20-22. (canceled)

23. An electronic device comprising:
a display device that comprises:
a display panel; and
a panel support layer disposed on the display panel,
wherein the panel support layer comprises:
a folding portion,
at least one non-folding portion disposed on at least one side of the folding portion,
a plurality of solid sections and a plurality of apertures alternately arranged at the folding portion, and
a cut line disposed between the apertures and the non-folding portion.
